(19) United States
(12) Patent Application Publication
(10) Pub. No.: US 2023/0105852 A1
(43) Pub. Date: Apr. 6, 2023

(54) NITRIDE SEMICONDUCTOR LIGHT-EMITTING ELEMENT

(71) Applicant: NIKKISO CO., LTD., Tokyo (JP)

(72) Inventors: Yusuke MATSUKURA, Ishikawa (JP); Cyril PERNOT, Ishikawa (JP)

(73) Assignee: NIKKISO CO., LTD., Tokyo (JP)

(21) Appl. No.: 17/947,463

(22) Filed: Sep. 19, 2022

(30) Foreign Application Priority Data
Sep. 21, 2021 (JP) 2021-153331

(51) Int. Cl. H01L 33/32; H01L 33/14; H01L 33/02

(52) U.S. Cl. CPC H01L 33/32; H01L 33/025; H01L 33/145

(57) ABSTRACT

A nitride semiconductor light-emitting element includes an n-type semiconductor layer; a p-type semiconductor layer; an active layer provided between the n-type semiconductor layer and the p-type semiconductor layer; and an electron blocking layer provided between the active layer and the p-type semiconductor layer. A film thickness of the electron blocking layer is not more than 100 nm. An average value of a hydrogen concentration over the electron blocking layer in a stacking direction of the n-type semiconductor layer, the active layer, the electron blocking layer and the p-type semiconductor layer is not more than 2.0×10¹⁸ atoms/cm³. A boundary portion between the p-type semiconductor layer and the electron blocking layer includes an n-type impurity.

### CROSS-REFERENCE TO RELATED APPLICATIONS

The present patent application claims the priority of Japanese patent application No. 2021/153331 filed on Sep. 21, 2021. and the entire contents of Japanese patent application No. 2021/153331 are hereby incorporated by reference.

### Technical Field

The present invention relates to a nitride semiconductor light-emitting element.

### Background Art

Patent Literature 1 discloses a gallium nitride-based compound semiconductor light-emitting element in which an undoped spacer layer having a thickness of not more than 100 nm is provided between a p-type gallium nitride-based compound semiconductor layer and an active layer. The undoped spacer layer in the gallium nitride-based compound semiconductor light-emitting element described in Patent Literature 1 is not more than 100 nm since drive voltage of the gallium nitride-based compound semiconductor light-emitting element increases when the undoped spacer layer is more than 100 nm. If the undoped spacer layer here is not more than 100 nm, a distance between the p-type gallium nitride-based compound semiconductor layer and the active layer is close and there is concern that hydrogen may diffuse from the p-type gallium nitride-based compound semiconductor layer into the active layer. Therefore, in the gallium nitride-based compound semiconductor light-emitting element described in Patent Literature 1, oxygen is included in the p-type gallium nitride-based compound semiconductor layer to suppress diffusion of hydrogen from the p-type gallium nitride-based compound semiconductor layer into the active layer.

### Citation List

### Patent Literature

Patent Literature 1: WO 2012/140844

### SUMMARY OF INVENTION

In case of the gallium nitride-based compound semiconductor light-emitting element described in Patent Literature 1, there is room for improvement in terms of suppressing diffusion of hydrogen into the active layer.

The invention was made in view of such circumstances and it is an object of the invention to provide a nitride semiconductor light-emitting element capable of suppressing diffusion of hydrogen into an active layer.

To achieve the object described above, the invention provides a nitride semiconductor light-emitting element, comprising:
an n-type semiconductor layer;
a p-type semiconductor layer;
an active layer provided between the n-type semiconductor layer and the p-type semiconductor layer; and
an electron blocking layer provided between the active layer and the p-type semiconductor layer,
wherein a film thickness of the electron blocking layer is not more than 100 nm,
wherein an average value of a hydrogen concentration over the electron blocking layer in a stacking direction of the n-type semiconductor layer, the active layer, the electron blocking layer and the p-type semiconductor layer is not more than 2.0×10¹⁸ atoms/cm³, and
wherein a boundary portion between the p-type semiconductor layer and the electron blocking layer comprises an n-type impurity.

### Advantageous Effects of Invention

According to the invention, it is possible to provide a nitride semiconductor light-emitting element capable of suppressing diffusion of hydrogen into an active layer.

### BRIEF DESCRIPTION OF DRAWINGS

FIG. 1 is a schematic diagram illustrating a configuration of a nitride semiconductor light-emitting element in an embodiment.

FIG. 2 is a graph showing silicon concentration distribution and Al secondary ion intensity distribution in a stacking direction for light-emitting elements as Samples 1 to 4 in Experimental Example.

FIG. 3 is a graph showing magnesium concentration distribution and Al secondary ion intensity distribution in the stacking direction for the light-emitting elements as Samples 1 to 4 in Experimental Example.

FIG. 4 is a graph showing hydrogen concentration distribution and Al secondary ion intensity distribution in the stacking direction for the light-emitting elements as Samples 1 to 4 in Experimental Example.

FIG. 5 is a graph showing initial light output and residual light output of the light-emitting elements as Samples 1 to 4 in Experimental Example.

### DESCRIPTION OF EMBODIMENTS

### Embodiment

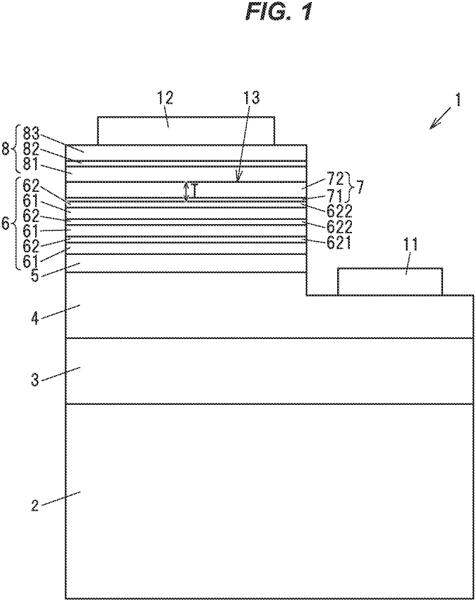

An embodiment of the invention will be described in reference to the FIG. 1. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1 in the present embodiment. In FIG. 1, the scale ratio of each layer of the nitride semiconductor light-emitting element 1 (hereinafter, also simply referred to as “the light-emitting element 1”) in a stacking direction is not necessarily the same as the actual scale ratio.

The light-emitting element 1 constitutes, e.g., a light-emitting diode (LED) or a semiconductor laser (LD: laser diode). In the present embodiment, the light-emitting element 1 constitutes a light-emitting diode (LED) that emits light with a wavelength in an ultraviolet region. Particularly, the light-emitting element 1 in the present embodiment constitutes a deep ultraviolet LED that emits deep ultraviolet light at a central wavelength of not less than 200 nm and not more than 365 nm. The light-emitting element 1 in the present embodiment can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type cladding layer 4 (the n-type semiconductor layer), a composition gradient layer 5, an active layer 6, an electron blocking layer 7 and a p-type semiconductor layer 8 in this order on a substrate 2. Each layer on the substrate 2 can be formed by a well-known epitaxial growth method such as the Metal Organic Chemical Vapor Deposition (MOCVD) method, the Molecular Beam Epitaxy (MBE) method, or Hydride Vapor Phase Epitaxy (HVPE) method. The light-emitting element 1 also includes an n-side electrode 11 provided on the n-type cladding layer 4, and a p-side electrode 12 provided on the p-type semiconductor layer 8.

Hereinafter, a direction of stacking the substrate 2, the buffer layer 3, the n-type cladding layer 4. the composition gradient layer 5, the active layer 6, the electron blocking layer 7 and the p-type semiconductor layer 8 (an up-and-down direction in FIG. 1) is simply referred to as “a stacking direction”. In addition, one side of the substrate 2 where each layer of the light-emitting element 1 is stacked (i.e.. an upper side in FIG. 1) is referred to as the upper side, and the opposite side (i.e., a lower side in FIG. 1) is referred to as the lower side. The terms “upper” and “lower” are used for descriptive purposes and do not limit the posture of the light-emitting element 1 with respect to the vertical direction when, e.g.. the light-emitting element 1 is in use. Each layer constituting the light-emitting element 1 has a thickness in the stacking direction.

As semiconductors constituting the light-emitting element 1, it is possible to use, e.g., binary to quaternary group III nitride semiconductors expressed by AlₓGa_{y}In_{1-x-y}N (0≤x≤1, 0≤y≤1, 0≤x+y≤1). In deep ultraviolet LEDs, Al_{z}Ga_{1-z}N system (0≤z≤1) not including indium is often used. The group III elements in semiconductors constituting the light-emitting element 1 may be partially substituted with boron (B) or thallium (Tl), etc. In addition, nitrogen (N) may be partially substituted with phosphorus (P), arsenic (As), antimony (Sb) or bismuth (Bi). etc. Next, each constituent element of the light-emitting element 1 will be described.

### Substrate 2

The substrate 2 is made of a material transparent to light (deep ultraviolet light in the present embodiment) emitted by the active layer 6. The substrate 2 is, e.g.. a sapphire (Al₂O₃) substrate. Alternatively, e.g., an aluminum nitride (AlN) substrate or an aluminum gallium nitride (AlGaN) substrate, etc., may be used as the substrate 2.

### Buffer Layer 3

The buffer layer 3 is formed on the substrate 2. In the present embodiment, the buffer layer 3 is made of aluminum nitride. When the substrate 2 is an aluminum nitride substrate or an aluminum gallium nitride substrate, the buffer layer 3 may not be necessarily included.

### N-Type Cladding Layer 4

The n-type cladding layer 4 is formed on the buffer layer 3. The n-type cladding layer 4 is an n-type semiconductor layer made of, e.g., AlₐGa₁₋ₐN (0≤a≤1) doped with an n-type impurity. An Al composition ratio a of the n-type cladding layer 4 is, e.g., preferably not less than 20%, and is more preferably not less than 25% and not more than 70%. In this regard, the Al composition ratio is also called AlN mole fraction.

The n-type cladding layer 4 is an n-type semiconductor layer doped with silicon (Si) as an n-type impurity. Alternatively, germanium (Ge), selenium (Se) or tellurium (Te), etc., may be used as the n-type impurity. The same applies to the semiconductor layers containing an n-type impurity other than the n-type cladding layer 4. The n-type cladding layer 4 has a film thickness of not less than 1 µm and not more than 4 µm. The n-type cladding layer 4 may have a single layer structure or may have a multilayer structure.

### Composition Gradient Layer 5

The composition gradient layer 5 is formed on the n-type cladding layer 4. The composition gradient layer 5 is made of Al_{b}Ga_{1-b}N (0<b≤1). In the composition gradient layer 5. an Al composition ratio at each position in the stacking direction is higher at an upper position. The composition gradient layer 5 may have a very small region in the stacking direction (e.g., a region of not more than 5% of the entire composition gradient layer 5 in the stacking direction) in which an Al composition ratio does not increase toward the upper side.

The composition gradient layer 5 is preferably configured such that the Al composition ratio at its lower end portion is substantially the same (e.g., a difference within 5%) as the Al composition ratio of the n-type cladding layer 4 and the Al composition ratio at its upper end portion is substantially the same (e.g., a difference within 5%) as an Al composition ratio of a barrier layer 61 adjacent to the composition gradient layer 5. By providing the composition gradient layer 5, it is possible to prevent a sudden change in the Al composition ratio between the barrier layer 61 and the n-type cladding layer 4 which are adjacent to the composition gradient layer 5 on the upper and lower sides. Occurrence of dislocations caused by lattice mismatch can thus be suppressed. As a result, it is possible to suppress consumption of electrons and holes due to non-luminescent recombination in the active layer 6, and light output of the light-emitting element 1 is improved. A film thickness of the composition gradient layer 5 can be. e.g., not less than 5 nm and not more than 20 nm. Silicon as an n-type impurity is preferably contained in the composition gradient layer 5 in the present embodiment, but it is not limited thereto.

### Active Layer 6

The active layer 6 is formed on the composition gradient layer 5. In the present embodiment, the active layer 6 is formed to have a multiple quantum well structure which includes plural well layers 62. In the present embodiment, the active layer 6 has three barrier layers 61 and three well layers 62 which are alternately stacked. In the active layer 6, the barrier layer 61 is located at the lower end and the well layer 62 is located at the upper end. The active layer 6 generates light at a predetermined wavelength by recombination of electrons with holes in the multiple quantum well structure. In the present embodiment, the active layer 6 is configured to have a band gap of not less than 3.4 eV so that deep ultraviolet light at a wavelength of not more than 365 nm is output. Particularly in the present embodiment, the active layer 6 is configured so that deep ultraviolet light at a central wavelength of not less than 200 nm and not more than 365 nm can be generated.

Each barrier layer 61 is made of Al_{c}Ga_{1-c}N (0<c≤1). The Al composition ratio c of each barrier layer 61 can be, e.g., not less than 75% and not more than 95%. Each barrier layer 61 has a film thickness of not less than 2 nm and not more than 12 nm.

Each well layer 62 is made of Al_{d}Ga_{1-d}N (0≤d<1). The three well layers 62 in the present embodiment are configured such that a lowermost well layer 621. which is the well layer 62 formed at the farthest position from the p-type semiconductor layer 8. has a different configuration from upper-side well layers 622 which are two well layers 62 other than the lowermost well layer 621.

A film thickness of the lowermost well layer 621 is not less than 1 nm greater than a film thickness of each of the upper-side well layers 622. In the present embodiment, the lowermost well layer 621 has a film thickness of not less than 4 nm and not more than 6 nm, and each upper-side well layer 622 has a film thickness of not less than 2 nm and not more than 4 nm. A difference between the film thickness of the lowermost well layer 621 and the film thickness of each upper-side well layer 622 can be, e.g., not less than 2 nm and not more than 4 nm. The film thickness of the lowermost well layer 621 can be, e.g., not less than double and not more than three times the film thickness of the upper-side well layer 622. By increasing the film thickness of the lowermost well layer 621 to larger than the film thickness of the upper-side well layers 622. the lowermost well layer 621 is flattened and flatness of each layer formed on the lowermost well layer 621 in the active layer 6 is also improved. As a result, it is possible to suppress variation in the Al composition ratio in each layer of the active layer 6 and it is possible to improve monochromaticity of output light.

An Al composition ratio of the lowermost well layer 621 is not less than 2% greater than an Al composition ratio of each of the two upper-side well layers 622. In the present embodiment, the lowermost well layer 621 has an Al composition ratio of not less than 35% and not more than 55%, and each upper-side well layer 622 has an Al composition ratio of not less than 25% and not more than 45%. A difference between the Al composition ratio of the lowermost well layer 621 and the Al composition ratio of each upper-side well layer 622 can be, e.g., not less than 10% and not more than 30%. The Al composition ratio of the lowermost well layer 621 can be, e.g., not less than 1.4 times and not more than 2.2 times the Al composition ratio of the upper-side well layer 622. By increasing the Al composition ratio of the lowermost well layer 621 to higher than the Al composition ratio of the upper-side well layers 622, a difference in the Al composition ratio between the n-type cladding layer 4 and the lowermost well layer 621 is reduced and crystallinity of the lowermost well layer 621 is improved. Then, the improved crystallinity of the lowermost well layer 621 improves crystallinity of each layer formed on the lowermost well layer 621 in the active layer 6. As a result, carrier mobility in the active layer 6 is improved and intensity of output light is improved.

In addition, e.g., the lowermost well layer 621 may be doped with silicon as an n-type impurity. This leads to formation of V-pits in the active layer 6, and such V-pits serve to stop advance of dislocations from the n-type cladding layer 4 side. In this regard, the upper-side well layers 622 may also contain an n-type impurity such as silicon. In addition, the active layer 6 has a multiple quantum well structure in the present embodiment but may have a single quantum well structure having only one well layer 62.

### Electron Blocking Layer 7

The electron blocking layer 7 serves to improve efficiency of electron injection into the active layer 6 by suppressing occurrence of the overflow phenomenon in which electrons leak from the active layer 6 to the p-type semiconductor layer 8. In the present embodiment, the electron blocking layer 7 is made of AlₑGa₁₋ₑN (0.7<e≤1). That is, in the present embodiment, an Al composition ratio e of the electron blocking layer 7 is not less than 70%. The electron blocking layer 7 has a first layer 71 and a second layer 72 which are stacked in this order from the lower side.

The first layer 71 is provided so as to be in contact with the upper-side well layer 622 located uppermost in the active layer 6. The first layer 71 preferably has an Al composition ratio of not less than 80% and the first layer 71 in the present embodiment is made of aluminum nitride (i.e., an Al composition ratio of 100%). The higher the Al composition ratio, the higher the electron blocking effect of suppressing passage of electrons. Thus, by forming the first layer 71 with a high Al composition ratio at a position adjacent to the active layer 6, a high electron blocking effect is obtained at a position close to the active layer 6 and this makes it easy to ensure electron existence probability in the three well layers 62.

Here, if a film thickness of the first layer 71 with a high Al composition ratio is increased excessively, there is concern that an electrical resistance value of the entire light-emitting element 1 becomes excessively large. For this reason, the film thickness of the first layer 71 is preferably not less than 0.5 nm and not more than 10 nm, more preferably, not less than 0.5 nm and not more than 5 nm. On the other hand, if the film thickness of the first layer 71 is reduced, it can increase the probability that electrons pass through the first layer 71 from the lower side to the upper side due to the tunnel effect. Therefore, in the light-emitting element 1 of the present embodiment, the second layer 72 is formed on the first layer 71 to suppress passage of electrons through the entire electron blocking layer 7.

The second layer 72 has an Al composition ratio smaller than the Al composition ratio of the first layer 71. The Al composition ratio of the second layer 72 can be, e.g., not less than 70% and not more than 90%. Meanwhile, a film thickness of the second layer 72 is preferably not less than the film thickness of the first layer 71 and is preferably not less than 1 nm and less than 100 nm from the viewpoint of ensuring that the sufficient electron blocking effect is obtained and also the electrical resistance value is reduced.

A film thickness T of the electron blocking layer 7, i.e., a total film thickness of the first layer 71 and the second layer 72 can be not less than 15 nm and not more than 100 nm. Magnesium as a p-type impurity, which is diffused from the p-type semiconductor layer 8 toward the active layer 6 when power is supplied to the light-emitting element 1, easily reaches the active layer 6 particularly when the film thickness T of the electron blocking layer 7 is not more than 100 nm. Then, when magnesium diffused from the p-type semiconductor layer 8 toward the active layer 6 easily reaches the active layer 6, hydrogen is also easily diffused into the active layer 6 at the same time since hydrogen is likely to bond with magnesium. When magnesium is diffused into the active layer 6, dislocations are likely to occur in the active layer 6 due to a difference in atomic radius between atoms of the matrix constituting the active layer 6 and magnesium. If it occurs, recombination of electrons with holes in the active layer 6 is likely to become non-luminescent recombination (e.g., recombination that generates vibration), which may decrease luminous efficiency. Meanwhile, when hydrogen is diffused into the active layer 6, the active layer 6 may deteriorate, resulting in that light output decreases as power supply time elapses, and life of the light-emitting element 1 may be shortened.

Therefore, in the present embodiment, an average value of a hydrogen concentration in the stacking direction over the entire electron blocking layer 7 is not more than 2.0×10¹⁸ atoms/cm³, preferably not more than 1.0×10¹⁸ atoms/cm³. Since the hydrogen concentration in the electron blocking layer 7 is relatively low, bonding of hydrogen to magnesium diffused from the p-type semiconductor layer 8 toward the active layer 6 can be suppressed and diffusion of hydrogen into the active layer 6 can thereby be suppressed.

Adjustment of the hydrogen concentration in each layer of the electron blocking layer 7 can be achieved by, e.g., adjusting a magnesium concentration in each layer of the electron blocking layer 7. That is, hydrogen is likely to be attracted to magnesium, hence, e.g., lowering the magnesium concentration in each layer of the electron blocking layer 7 allows the hydrogen concentration in each layer of the electron blocking layer 7 to be lowered. From the viewpoint of lowering the hydrogen concentration in each layer of the electron blocking layer 7, the magnesium concentration at each position of each layer of the electron blocking layer 7 in the stacking direction is preferably not more than 5.0×10¹⁸ atoms/cm³ and is more preferably at the background level. The magnesium concentration at the background level is a magnesium concentration detected when magnesium is not doped.

In the present embodiment, each layer of the electron blocking layer 7 is an undoped layer. Alternatively, each layer of the electron blocking layer 7 can be a layer containing an n-type impurity, a layer containing a p-type impurity, or a layer containing both an n-type impurity and a p-type impurity. When each layer of the electron blocking layer 7 contains an impurity, the impurity in each layer of the electron blocking layer 7 may be contained in the entire portion of each layer of the electron blocking layer 7 or may be contained in a part of each layer of the electron blocking layer 7. Magnesium (Mg) can be used as the p-type impurity to be included in each layer of the electron blocking layer 7, but zinc (Zn), beryllium (Be), calcium (Ca), strontium (Sr), barium (Ba) or carbon (C), etc., may be used other than magnesium. In addition, in the entire electron blocking layer 7, an average of each impurity concentration in the stacking direction is preferably not more than 5.0×10¹⁸ atoms/cm³. The reach of hydrogen, which is diffused from the p-type semiconductor layer 8 toward the active layer 6, to the active layer 6 is suppressed by lowering the impurity concentrations in each layer of the electron blocking layer 7. The electron blocking layer 7 may alternatively be composed of a single layer.

### Boundary Portion 13 Between Electron Blocking Layer 7 and P-Type Semiconductor Layer 8

A boundary portion 13 between the electron blocking layer 7 and the p-type semiconductor layer 8 contains silicon as an n-type impurity. Silicon contained in the boundary portion 13 is provided to suppress diffusion of magnesium and hydrogen from the p-type semiconductor layer 8 into the active layer 6. That is, since the boundary portion 13 between the electron blocking layer 7 and the p-type semiconductor layer 8 contains silicon, magnesium in the p-type semiconductor layer 8 is stopped by silicon in the boundary portion 13. Diffusion of magnesium contained in the p-type semiconductor layer 8 into the active layer 6 is thereby suppressed. In this regard, a p-type impurity and an n-type impurity, particularly magnesium and silicon, are likely to be attracted to each other. Furthermore, since hydrogen is likely to bond with magnesium, diffusion of hydrogen from the p-type semiconductor layer 8 into the active layer 6 is also suppressed by suppressing diffusion of magnesium from the p-type semiconductor layer 8 into the active layer 6. In this regard, magnesium is often used as a p-type impurity in group III-V semiconductors.

Silicon in the boundary portion 13 should be present in at least one of the following states: a solid solution state in the crystal; a cluster state; and a state in which a compound containing silicon is precipitated. The solid solution state of silicon in the crystal is a state in which silicon is doped in aluminum gallium nitride constituting the boundary portion 13, i.e., a state in which silicon is located at lattice positions of aluminum gallium nitride. Meanwhile, the cluster state of silicon is a state in which silicon excessively doped in aluminum gallium nitride constituting the boundary portion 13 is present at the lattice positions of aluminum gallium nitride and is also present as aggregates, etc.. between the lattice positions. The state in which a compound containing silicon is precipitated is a state in which, e.g., silicon nitride, etc., is formed. In the boundary portion 13 between the electron blocking layer 7 and the p-type semiconductor layer 8, a silicon-containing layer may be formed or silicon-containing portions may be scattered in a plane direction orthogonal to the stacking direction.

In silicon concentration distribution in the stacking direction of the light-emitting element 1, a peak value of a silicon concentration in the boundary portion 13 preferably satisfies not less than 1.0×10¹⁸ atoms/cm³ and not more than 1.0×10²⁰ atoms/cm³. By setting to not less than 1.0×10¹⁸ atoms/cm³ it is easy to further suppress diffusion of magnesium. Meanwhile, by setting to not more than 1.0×10²⁰ atoms/cm³, it is possible to suppress a decrease in crystallinity of the second layer 72 and a first p-type cladding layer 81 which are adjacent to the boundary portion 13. Furthermore, in the silicon concentration distribution in the stacking direction of the light-emitting element 1, the peak value of the silicon concentration in the boundary portion 13 more preferably satisfies not less than 3.0x10¹⁸ atoms/cm³ and not more than 5.0×10¹⁹ atoms/cm³. Then, by configuring such that the electron blocking layer 7 located between the boundary portion 13 containing silicon and the active layer 6 is formed as a layer containing little impurities (particularly an undoped layer) as described above and the p-type semiconductor layer 8 located on the opposite side to the active layer 6 relative to the boundary portion 13 is formed as a layer containing a relatively large amount of a p-type impurity, it is possible to suppress diffusion of magnesium and hydrogen from the p-type semiconductor layer 8 into the active layer 6 while increasing a carrier concentration in the p-type semiconductor layer 8.

### P-Type Semiconductor Layer 8

The p-type semiconductor layer 8 is formed on the second layer 72. In the present embodiment, an Al composition ratio of the p-type semiconductor layer 8 is less than 70%. In the present embodiment, the p-type semiconductor layer 8 has the first p-type cladding layer 81. a second p-type cladding layer 82 and a p-type contact layer 83 which are stacked in this order from the lower side.

The first p-type cladding layer 81 is provided so as to be in contact with the second layer 72. The first p-type cladding layer 81 is made of Al_{f}Ga_{1-f}N (0<f≤1) containing magnesium as a p-type impurity. A magnesium concentration in the first p-type cladding layer 81 can be not less than 1.0×10¹⁸ atoms/cm³ and not more than 5.0x10¹⁹ atoms/cm³. An Al composition ratio f of the first p-type cladding layer 81 can be not less than 45% and not more than 65%. The first p-type cladding layer 81 has a film thickness of not less than 15 nm and not more than 35 nm.

The second p-type cladding layer 82 is made of Al_{g}Ga_{1-g}N (0<g≤1) containing magnesium as a p-type impurity. A magnesium concentration in the second p-type cladding layer 82 can be not less than 1.0×10¹⁸ atoms/cm³ and not more than 5.0×10¹⁹ atoms/cm³. in the same manner as the magnesium concentration in the first p-type cladding layer 81.

In the second p-type cladding layer 82, an Al composition ratio in the stacking direction decreases toward the upper side. In this regard, the second p-type cladding layer 82 may have a very small region in the stacking direction (e.g., a region of not more than 5% of the entire second p-type cladding layer 82 in the stacking direction) in which an Al composition ratio does not decrease toward the upper side.

The second p-type cladding layer 82 is preferably configured such that the Al composition ratio at its lower end portion is substantially the same (e.g.. a difference within 5%) as the Al composition ratio of the first p-type cladding layer 81 and the Al composition ratio at its upper end portion is substantially the same (e.g., a difference within 5%) as an Al composition ratio of the p-type contact layer 83. A sudden change in the Al composition ratio between the p-type contact layer 83 and the first p-type cladding layer 81, which are adjacent to the second p-type cladding layer 82 on the upper and lower sides, is suppressed by providing the second p-type cladding layer 82. Occurrence of dislocations caused by lattice mismatch can thereby be suppressed. As a result, it is possible to suppress consumption of electrons and holes due to non-luminescent recombination in the active layer 6 and light output of the light-emitting element 1 is improved. A film thickness of the second p-type cladding layer 82 can be, e.g., not less than 2 nm and not more than 4 nm.

The p-type contact layer 83 is a layer connected to the p-side electrode 12 and is made of AlₕGa₁₋ₕN (0≤h≤1) doped with a high concentration of magnesium as a p-type impurity. A magnesium concentration in the p-type contact layer 83 can be not less than 5.0×10¹⁸ atoms/cm³ and not more than 5.0×10²¹ atoms/cm³. In the present embodiment, the p-type contact layer 83 is made of p-type gallium nitride (GaN). The p-type contact layer 83 is configured to have a low Al composition ratio h to achieve an ohmic contact with the p-side electrode 12 and, from such a viewpoint, is preferably made of p-type gallium nitride. A film thickness of the p-type contact layer 83 can be, e.g., not less than 10 nm and not more than 25 nm.

The p-type impurity contained in each layer of the p-type semiconductor layer 8 is magnesium, but may be zinc, beryllium, calcium, strontium, barium or carbon, etc.

### N-Side Electrode 11

The n-side electrode 11 is formed on a surface of the n-type cladding layer 4 which is exposed on the upper side. The n-side electrode 11 can be made of, e.g., a multilayered film formed by sequentially stacking titanium (Ti), aluminum, titanium and gold (Au) on the n-type cladding layer 4.

### P-Side Electrode 12

The p-side electrode 12 is formed on the p-type contact layer 83. The p-side electrode 12 is a reflective electrode that reflects deep ultraviolet light emitted from the active later 6. The p-side electrode 12 has a reflectance of not less than 50%, preferably not less than 60%, at the central wavelength of light emitted by the active later 6. The p-side electrode 12 is preferably a metal containing rhodium (Rh). The metal containing rhodium is highly reflective of deep ultraviolet light and is also highly bondable to the p-type contact layer 83. In the present embodiment, the p-side electrode 12 is composed of a rhodium monolayer. Light emitted upward from the active layer 6 is reflected at an interface between the p-side electrode 12 and the p-type semiconductor layer 8.

In the present embodiment, the light-emitting element 1 is flip-chip mounted on a package substrate (not shown). That is, the light-emitting element 1 is mounted such that a side in the stacking direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side (i.e., on the lower side). However, it is not limited thereto and the light-emitting element 1 may be mounted on the package substrate by wire bonding, etc. In addition, although the light-emitting element 1 in the present embodiment is a so-called lateral light-emitting element 1 in which both the n-side electrode 11 and the p-side electrode 12 are provided on the upper side of the light-emitting element 1, the light-emitting element 1 is not limited thereto and may be a vertical light-emitting element 1. The vertical light-emitting element 1 is a light-emitting element 1 in which the active layer 6 is sandwiched between the n-side electrode 11 and the p-side electrode 12. In this regard, when the light-emitting element 1 is of the vertical type, the substrate 2 and the buffer layer 3 are preferably removed by laser lift-off, etc.

### Numerical Values of Element Concentrations

Numerical values of the above-described element concentrations (the hydrogen concentration, the silicon concentration, etc.) at each position of the light-emitting element 1 in the stacking direction are values obtained using secondary-ion mass spectrometry (SIMS). A method for measuring the element concentrations will be described since measurement results can vary greatly even when using secondary-ion mass spectrometry depending on the number and type, etc., of elements for which element concentrations are measured simultaneously.

The following processes were separately performed to measure the element concentrations at each position of the light-emitting element 1 in the stacking direction: a process in which concentrations of the four elements: silicon, oxygen, carbon, and hydrogen, and secondary ion intensity of Al are measured simultaneously; and a process in which the magnesium concentration and secondary ion intensity of Al are measured simultaneously. PHI ADEPT1010 manufactured by ULVAC-PHI, Inc. can be used for measurement of these elements. In this regard, in secondary-ion mass spectrometry, it is not possible to accurately measure the element concentrations in a layer constituting the outermost surface (in the p-type contact layer 83 in the present embodiment), hence, the numerical values of the element concentrations (the oxygen concentration, the hydrogen concentration, the silicon concentration, etc.) at each position of the light-emitting element 1 in the stacking direction described above are values which do not take into account the values measured in the region in which accurate measurement is impossible. The measurement conditions can be set as follows: use of Cs+ as a primary ion species, primary accelerating voltage of 2.0 kV, and a detection area of 88×88 µm²

### Functions and Effects of the Embodiment

In the present embodiment, the film thickness T of the electron blocking layer 7 is not more than 100 nm. If the thickness of the electron blocking layer 7 is increased, it causes an increase in the electrical resistance value of the entire light-emitting element 1 due to the high Al composition ratio. However, in the present embodiment the electrical resistance value of the entire light-emitting element 1 can be reduced by setting the film thickness T of the electron blocking layer 7 to not more than 100 nm. Here, in case that the film thickness T of the electron blocking layer 7 is not more than 100 nm and when not taking any measures, the p-type impurity (magnesium) is likely to be diffused from the p-type semiconductor layer 8 into the active layer 6 through the electron blocking layer 7. Furthermore, when magnesium diffused from the p-type semiconductor layer 8 toward the active layer 6 easily reaches the active layer 6, hydrogen is also easily diffused into the active layer 6 at the same time since hydrogen is likely to bond with magnesium. When magnesium is diffused into the active layer 6, dislocations are likely to occur in the active layer 6 due to a difference in atomic radius between atoms of the matrix constituting the active layer 6 and magnesium. If it occurs, recombination of electrons with holes in the active layer 6 is likely to become non-luminescent recombination (e.g., recombination that generates vibration), which may decrease luminous efficiency. Meanwhile, when hydrogen is diffused into the active layer 6, the active layer 6 may deteriorate, resulting in that light output decreases as power supply time elapses, and life of the light-emitting element 1 may be shortened.

For this reason, the boundary portion 13 between the p-type semiconductor layer 8 and the electron blocking layer 7 contains an n-type impurity (silicon) in the present embodiment. Due to silicon contained in the boundary portion 13, magnesium trying to diffuse from the p-type semiconductor layer 8 toward the active layer 6 is stopped by silicon in the boundary portion 13 since magnesium is likely to be attracted to silicon. Magnesium diffusing from the p-type semiconductor layer 8 toward the active layer 6 thus can be reduced, resulting in that diffusion of hydrogen bonding with magnesium into the active layer can be suppressed. Furthermore, in the present embodiment, the average value of the hydrogen concentration in the stacking direction over the electron blocking layer 7 is not more than 2.0×10¹⁸ atoms/cm³. Therefore, even if magnesium is diffused from the p-type semiconductor layer 8 into the active layer 6, diffusion of hydrogen into the active layer 6 can be suppressed since bonding of hydrogen to magnesium diffused into active layer 6 can be suppressed.

In addition, the average value of the hydrogen concentration in the stacking direction over the electron blocking layer 7 further satisfies not more than 1.0×10¹⁸ atoms/cm³. It is thereby possible to further suppress diffusion of hydrogen into the active layer 6.

In addition, in silicon concentration distribution in the stacking direction in the light-emitting element 1, the peak value at the boundary portion 13 is not less than 1.0×10¹⁸ atoms/cm³. Therefore, it is possible to further suppress diffusion of magnesium and hydrogen from the p-type semiconductor layer 8 toward the active layer 6.

In addition, in silicon concentration distribution in the stacking direction in the light-emitting element 1, the peak value at the boundary portion 13 further satisfies not more than 1.0×10²⁰ atoms/cm³. Therefore, it is possible to suppress a decrease in crystallinity of the second layer 72 and a first p-type cladding layer 81 which are adjacent to the boundary portion 13.

In addition, an average value of an n-type impurity concentration in the stacking direction over the electron blocking layer 7 and an average value of a p-type impurity concentration in the stacking direction over the electron blocking layer 7 are each not more than 5.0×10¹⁸ atoms/cm³. By lowering the impurity concentrations in the electron blocking layer 7 in this manner, it is possible to suppress diffusion of hydrogen from the p-type semiconductor layer 8 into the active layer 6 through the electron blocking layer 7.

As described above, according to the present embodiment, it is possible to provide a nitride semiconductor light-emitting element capable of suppressing diffusion of hydrogen into the active layer.

### Experimental Example

This Experimental Example is an example in which initial light output and residual light output were evaluated for light-emitting elements as Samples 1 to 4 with various magnesium concentrations and hydrogen concentrations. Among constituent elements in this Experimental Example, the constituent elements denoted by the same names as those in the above-mentioned embodiment indicate the same constituent elements as those in the above-mentioned embodiment, unless otherwise specified.

Firstly, the light-emitting elements as Samples 1 to 4 will be described. Table 1 shows film thickness, Al composition ratio, silicon concentration, magnesium concentration and hydrogen concentration of each layer of the light-emitting elements as Samples 1 to 4.

TABLE 1

| Structure | | Film thickness | Al composition ratio [%] | Si concentration [atoms/cm³] | Mg_{.} concentration [atoms/cm³] | H concentration [atoms/cm³] |
|---|---|---|---|---|---|---|
| Substrate | | 430 µm±2.5 µm | | BG | BG | BG |
| Buffer layer | | 2000±200 nm | 100 | BG | BG | BG |
| N-type cladding layer | | 2000±200 nm | 55±10 | (1.50±1.00)E+19 | BG | BG |
| Composition gradient layer | | 15±5 nm | 55→85 | BG - Peak concentration in Lowermost well layer | BG | BG |
| Active layer (3QW) | Barrier layer | 7±5 nm | 85±10 | BG - Peak concentration in Lowermost well layer | BG | BG |
| | Well layer (Lowermost well layer) | 5±1 mn | 45±10 | Peak concentration : (3.50±2.50)E+19 | BG | BG |
| | Barrier layer | 7±5 nm | 85±10 | BG .. Peak concentration in Lowermost well layer | BG | BG |
| | Well layer (Upper-side well layer) | 3±1 nm | 35±10 | BG - 1.00E+19 | BG | BG |
| | Barrier layer | 7±5 nm | 85±10 | BG - 1.00E+19 | BG - 1.00E+19 | BG 1.00E+19 |
| | Well layer (Upper-side well layer) | 3±1 nm | 35±10 | BG 1.00E+18 | BG - 1.00E+19 | BG - 1.00E+19 |
| Electron blocking layer | First layer | 2±1 nm | 95±5 | Peak concentration in Boundary portion (2.00±1.00)E+19 Other than Boundary portion BG | Average value | Average value |
| | Second layer | 20±5 nm | 80±10 | | Sample 1: 1.97E+17 | Sample 1. 2.80E+17 |
| | | | | | Sample 2: 3.96E+18 | Sample 2: 7.14E+17 |
| | | | | | Sample 3: 6.56E+18 | Sample 3 2.69E+18 |
| | | | | | Sample 4: 7.80E+18 | Sample 4: 4.15E+18 |
| P-type semiconductor layer | First p-type cladding layer | 25±10 nm | 55±10 | | 1.00E+18-5.00E+19 | 1.00E+18-5.00E+19 |
| | Second p-type cladding layer | 3±1 nm | 55→0 | | 1.00E+18-5.00E+19 | 1.00E+18-5.00E+19 |
| | P-type contact layer | 20±5 nm | 0 | | 5.00E+18-5.00E+21 | BG-5.00E+21 |

The Al composition ratio of each layer shown in Table 1 is a value estimated from secondary ion intensity of Al measured by SIMS. In Table 1, “BG” indicates the background level. The figure in the column of Al composition ratio for Composition gradient layer in Table 1 indicates that the Al composition ratio of the composition gradient layer in the stacking direction gradually increases from 55% to 85% from the lower end to the upper end of the composition gradient layer. Likewise, the figure in the column of Al composition ration for Second p-type cladding layer in Table 1 indicates that the Al composition ratio of the second p-type cladding layer in the stacking direction gradually decreases from 55% to 0% from the lower end to the upper end of the second p-type cladding layer. The figures in the column of Mg concentration for Electron blocking layer in Table 1 are average values of the magnesium concentration in the stacking direction over the electron blocking layer for Samples 1 to 4. The figures in the column of H concentration for Electron blocking layer in Table 1 are average values of the hydrogen concentration in the stacking direction over the electron blocking layer for Samples 1 to 4. In this regard, the average values of the magnesium concentration and the average values of the hydrogen concentration for Electron blocking layer in Table 1 are values which do not take into account the results measured in a region from a boundary between the electron blocking layer and the active layer to a position 5 nm away from the boundary toward the p-type semiconductor layer, and a region from a boundary between the electron blocking layer and the p-type semiconductor layer to a position 5 nm away from the boundary toward the active layer. This is because these regions are where accurate values are not obtained by SIMS.

As understood from Table 1, Samples 1 to 4 have different average values of the magnesium concentration in the stacking direction over the electron blocking layer and different average values of the hydrogen concentration in the stacking direction over the electron blocking layer. In other words, both the average values of the magnesium concentration in the stacking direction over the electron blocking layer and the average values of the hydrogen concentration in the stacking direction over the electron blocking layer become larger in the order of Sample 1, Sample 2, Sample 3, and Sample 4. Other than this, Samples 1 to 4 have the same configuration.

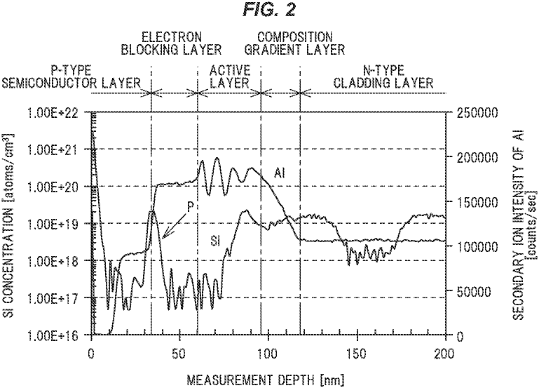

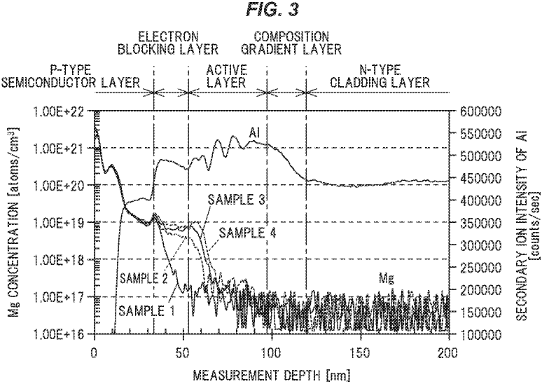

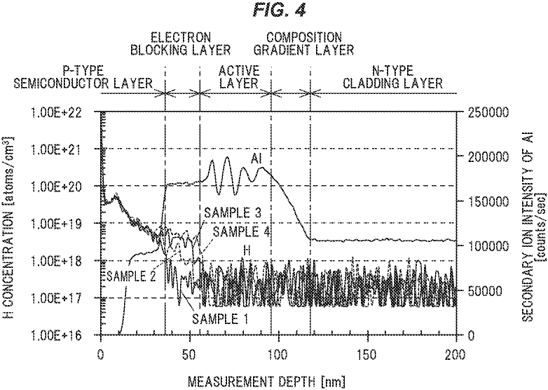

FIG. 2 shows silicon concentration distribution and Al secondary ion intensity distribution in the stacking direction for each sample light-emitting element. FIG. 3 shows magnesium concentration distribution and Al secondary ion intensity distribution in the stacking direction for each sample light-emitting element. FIG. 4 shows hydrogen concentration distribution and Al secondary ion intensity distribution in the stacking direction for each sample light-emitting element. Regarding both silicon concentration distribution and Al secondary ion intensity distribution in the stacking direction in FIG. 2, only the results for Sample 1 are shown as a typical example since Samples 1 to 4 do not have significant difference. Regarding Al secondary ion intensity distribution in the stacking direction in FIGS. 3 and 4, only the result for Sample 1 is shown as a typical example since Samples 1 to 4 do not have significant difference. In addition, regarding magnesium concentration distribution and hydrogen concentration distribution in FIGS. 3 and 4, the results for Samples 1 and 3 are indicated by solid lines and the results for Samples 2 and 4 are indicated by dashed lines for the sake of ease of viewing the graphs. In addition, rough locations of boundaries of the respective layers of the light-emitting elements as Samples 1 to 4 are shown in FIGS. 2 to 4.

In FIG. 2, a peak P of the silicon concentration emerges at a boundary portion between the electron blocking layer and the p-type semiconductor layer. Here, the peak P in FIG. 2 appears to have some width, but this is a matter of measurement and the thickness of the silicon-containing portion of the boundary portion is actually substantially zero. In addition, comparison of FIGS. 3 and 4 shows that the hydrogen concentration increases or decreases together with the magnesium concentration. That is, the electron blocking layer containing a larger amount of magnesium has a higher hydrogen concentration.

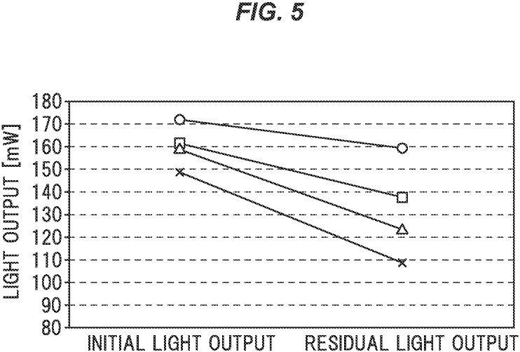

Initial light output and residual light output were also measured on Samples 1 to 4. The initial light output is light output when supplying a current of 500 mA to Samples 1 to 4 immediately after being manufactured. Meanwhile, the residual light output is light output of Samples 1 to 4 after continuously passing a current of 500 mA for 112 hours. Measurement of light output was conducted by a photodetector placed under each of Samples 1 to 4. The result is shown in the graph in FIG. 5. In FIG. 5, the results of Sample 1 are plotted with circles, the results of Sample 2 are plotted with diamonds, the results of Sample 3 are plotted with triangles, and the results of Sample 4 are plotted with x symbols.

The results for Samples 1 to 4 in FIG. 5 show that the lower the average hydrogen concentration in the electron blocking layer, the higher the initial light output. The results for Samples 1 to 4 also show that the lower the average hydrogen concentration in the electron blocking layer, the higher the residual light output. Furthermore, the slopes of the graphs for Samples 3 and 4 are different from those for Samples 1 and 2, showing that the rate of decrease in light output is slower for Samples 1 and 2. This indicates that life of Samples 1 and 2, i.e., the light-emitting elements in which the average value of the hydrogen concentration in the stacking direction over the electron blocking layer satisfies not more than 2.0×10¹⁸ atoms/cm³. can be extended. This result also shows that the average value of the hydrogen concentration in the stacking direction over the electron blocking layer preferably satisfies particularly 1.0×10¹⁸ atoms/cm³. In addition, Sample 1, i.e., the light-emitting element in which the average value of the hydrogen concentration in the stacking direction over the electron blocking layer is 2.80×10¹⁷ atoms/cm³, has higher initial light output and higher residual light output and also longer life than Samples 2 to 4 in which said average value is more than 7.0×10¹⁷ atoms/cm³. Therefore, it is further preferable that the average value of the hydrogen concentration in the stacking direction over the electron blocking layer satisfy not more than 7.0×10¹⁷ atoms/cm³.

### Summary of the Embodiment

Technical ideas understood from the embodiment will be described below citing the reference signs, etc., used for the embodiment. However, each reference sign, etc.. described below is not intended to limit the constituent elements in the claims to the members, etc., specifically described in the embodiment.

[1] The first aspect of the invention is a nitride semiconductor light-emitting element (1), comprising: an n-type semiconductor layer (4): a p-type semiconductor layer (8); an active layer provided between the n-type semiconductor layer (4) and the p-type semiconductor layer (8): and an electron blocking layer (7) provided between the active layer and the p-type semiconductor layer (8), wherein a film thickness (T) of the electron blocking layer (7) is not more than 100 nm, wherein an average value of a hydrogen concentration over the electron blocking layer (7) in a stacking direction of the n-type semiconductor layer (4), the active layer, the electron blocking layer (7) and the p-type semiconductor layer (8) is not more than 2.0×10¹⁸ atoms/cm³, and wherein a boundary portion (13) between the p-type semiconductor layer (8) and the electron blocking layer (7) comprises an n-type impurity.

It is thereby possible to suppress diffusion of hydrogen from the p-type semiconductor layer into the active layer.

[2] The second aspect of the invention is that, in the first aspect, the average value of the hydrogen concentration in the stacking direction over the electron blocking layer (7) further satisfies not more than 1.0×10¹⁸ atoms/cm³.

It is thereby possible to further suppress diffusion of the p-type impurity and hydrogen from the p-type semiconductor layer toward the active layer.

[3] The third aspect of the invention is that, in the first or second aspect, a peak value at the boundary portion (13) in concentration distribution of the n-type impurity in the stacking direction is not less than 1.0×10¹⁸ atoms/cm³.

It is thereby possible to further suppress diffusion of the p-type impurity and hydrogen from the p-type semiconductor layer toward the active layer.

[4] The fourth aspect of the invention is that, in the third aspect, the peak value further satisfies not more than 1.0×10²⁰ atoms/cm³.

It is thereby possible to suppress a decrease in crystallinity of the electron blocking layer and the p-type semiconductor layer which are adjacent to the boundary portion.

[5] The fifth aspect of the invention is that, in any one of the first to fourth aspect, an average value of an n-type impurity concentration in the stacking direction over the electron blocking layer (7) and an average value of a p-type impurity concentration in the stacking direction over the electron blocking layer (7) are each not more than 5.0×10¹⁸ atoms/cm³.

It is thereby possible to further suppress diffusion of the p-type impurity and hydrogen from the p-type semiconductor layer toward the active layer.

### Additional Note

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

### REFERENCE SIGNS LIST

1 LIGHT-EMITTING ELEMENT
13 BOUNDARY PORTION
4 N-TYPE CLADDING LAYER (N-TYPE SEMICONDUCTOR LAYER)
6 ACTIVE LAYER
7 ELECTRON BLOCKING LAYER
8 P-TYPE SEMICONDUCTOR LAYER
T FILM THICKNESS OF ELECTRON BLOCKING LAYER

1. A nitride semiconductor light-emitting element, comprising:
an n-type semiconductor layer;
a p-type semiconductor layer;
an active layer provided between the n-type semiconductor layer and the p-type semiconductor layer; and
an electron blocking layer provided between the active layer and the p-type semiconductor layer,
wherein a film thickness of the electron blocking layer is not more than 100 nm,
wherein an average value of a hydrogen concentration over the electron blocking layer in a stacking direction of the n-type semiconductor layer, the active layer, the electron blocking layer and the p-type semiconductor layer is not more than 2.0×10¹⁸ atoms/cm³, and
wherein a boundary portion between the p-type semiconductor layer and the electron blocking layer comprises an n-type impurity.

2. The nitride semiconductor light-emitting element according to claim 1, wherein the average value of the hydrogen concentration in the stacking direction over the electron blocking layer further satisfies not more than 1.0×10¹⁸ atoms/cm³.

3. The nitride semiconductor light-emitting element according to claim 1, wherein a peak value at the boundary portion in concentration distribution of the n-type impurity in the stacking direction is not less than 1.0×10¹⁸ atoms/cm³.

4. The nitride semiconductor light-emitting element according to claim 3, wherein the peak value further satisfies not more than 1.0×10²⁰ atoms/cm³.

5. The nitride semiconductor light-emitting element according to claim 1, wherein an average value of an n-type impurity concentration in the stacking direction over the electron blocking layer and an average value of a p-type impurity concentration in the stacking direction over the electron blocking layer are each not more than 5.0×10¹⁸ atoms/cm³.
